(19) United States
(12) Patent Application Publication
(10) Pub. No.: US 2009/0184337 A1
(43) Pub. Date: Jul. 23, 2009

(54) Light-Emitting Diode, Package Structure Thereof and Manufacturing Method for the Same

(76) Inventors: Ben Fan, He Shan City (CN); Hsin-Chuan Weng, He Shan City (CN); Kuo-Kuang Yeh, He Shan City (CN)

Correspondence Address: KAMRATH & ASSOCIATES P.A., 4825 OLSON MEMORIAL HIGHWAY, SUITE 245, GOLDEN VALLEY, MN, 55422, US

(21) Appl. No.: 12/351,011

(22) Filed: Jan. 9, 2009

(30) Foreign Application Priority Data
Jan. 19, 2008 (CN) 200810025948.7

(51) Int. Cl. H01L 33/00; H01L 51/52; H01L 21/04

(52) U.S. Cl. 257/99; 257/103; 438/22; 257/E33.064; 257/E33.045; 257/E21.04

(57) ABSTRACT

A light-emitting diode includes a sapphire substrate, an n-type semiconductor, a light-emitting layer, a p-type semiconductor layer, an anode and a conductive material. The n-type semiconductor layer is formed on the sapphire substrate and has a side surface, a center section and an edge around the center portion. The light-emitting layer is formed on the n-type semiconductor layer. The p-type semiconductor layer is formed on the light-emitting layer. The anode is formed on the p-type semiconductor layer. The conductive material is formed on the bottom surface of the sapphire substrate and is in contact with the n-type semiconductor layer.

### BACKGROUND OF THE INVENTION

1. Field of Invention

The present invention relates to a light-emitting diode, and more particularly to a light-emitting diode, a package structure thereof and a manufacturing method for the same.

2. Description of the Related Art

A light-emitting diode (LED) is a forward-biased p-n junction diode made of semiconductor materials. The light-emitting principle of the light-emitting diode is described as follows. When a forward electrical current is applied to two sides of the p-n junction of the light-emitting diode, non-equilibrium carriers (electrons-holes) recombine to emit light. The foregoing light-emitting process primarily corresponds to a spontaneous light-emitting process. Materials for manufacturing the light-emitting diode are heavily doped and to create the p-n junction. Under a thermal equilibrium condition, the n-type region has a lot of mobile electrons and the p-type region has a lot of holes. The p-n junction serves as an insulator and prevents electrons and holes from recombining. However, when a forward electrical current is applied to the p-n junction, electrons can overcome the built-in potential of the p-n junction and enter a side of the p-n junction near the p-type region. When electrons meet hole in the side of the p-n junction, recombination occurs and light emits.

Generally, a conventional light-emitting diode is manufactured by forming a laminated structure comprising an n-type semiconductor layer, a light-emitting layer and a p-type semiconductor layer on a substrate. When the conventional light-emitting diode uses different materials and structures, a wave length of the light emitted from the conventional light-emitting diode is also changed. For example, blue and green light-emitting diodes usually use sapphire as a substrate and GaInN epitaxial structure as a laminated structure. Because the sapphire is used as the substrate, an anode and a cathode of the conventional light-emitting diode are formed on the same surface of the substrate Thus, the electrodes of the conventional light-emitting diode occupy a large area of the conventional light-emitting diode chip. That may result in an uneven distribution in the conventional light-emitting diode. Additionally, the brightness of the conventional light-emitting diode may decrease due to the light absorption of the electrodes.

To overcome the shortcomings, the present invention provides a light-emitting diode, package structure and manufacturing method thereof to mitigate or obviate the aforementioned problems.

### SUMMARY OF THE INVENTION

The primary objective of the present invention is to provide a light-emitting diode that can improve the diffusion current in the light-emitting diode.

The other objective of the present invention is to provide a light-emitting diode with raised brightness.

A light-emitting diode in accordance with the present invention comprises a sapphire substrate, an n-type semiconductor, a light-emitting layer, a p-type semiconductor layer, an anode and a conductive material. The n-type semiconductor layer is formed on the sapphire substrate and has a side surface, a center section and an edge around the center portion. The light-emitting layer is formed on the n-type semiconductor layer. The p-type semiconductor layer is formed on the light-emitting layer. The anode is formed on the p-type semiconductor layer. The conductive material is formed on the bottom surface of the sapphire substrate and is in contact with the n-type semiconductor layer. The invention also includes a package structure of a light-emitting diode and a manufacturing method of the light-emitting diode.

Other objectives, advantages and novel features of the invention will become more apparent from the following detailed description when taken in conjunction with the accompanying drawings.

### BRIEF DESCRIPTION OF THE DRAWINGS

FIG. 1 is a cross sectional side view of a first embodiment of a light-emitting diode in accordance with the present invention;

FIG. 2 is a cross sectional side view of a second embodiment of the light-emitting diode in accordance with the present invention;

FIG. 3 is a cross sectional side view of a third embodiment of the light-emitting diode in accordance with the present invention;

FIGS. 4A to 4E are cross sectional side views of steps of an embodiment of a manufacturing method of the light-emitting diode in accordance with the present invention;

FIG. 5 is a cross sectional side view of a first embodiment of a package structure of the light-emitting diode in accordance with the present invention;

FIG. 6 is a cross sectional side view of a second embodiment of the package structure of the light-emitting diode in accordance with the present invention;

FIG. 7 is a side view in partial section of a third embodiment of the package structure of the light-emitting diode in accordance with the present invention; and

FIG. 8 is a top view of the first embodiment of the light-emitting diode in FIG. 1; and

FIG. 9 is a cross sectional side view of another embodiment of a light-emitting diode in accordance with the present invention.

### DETAILED DESCRIPTION OF THE INVENTION

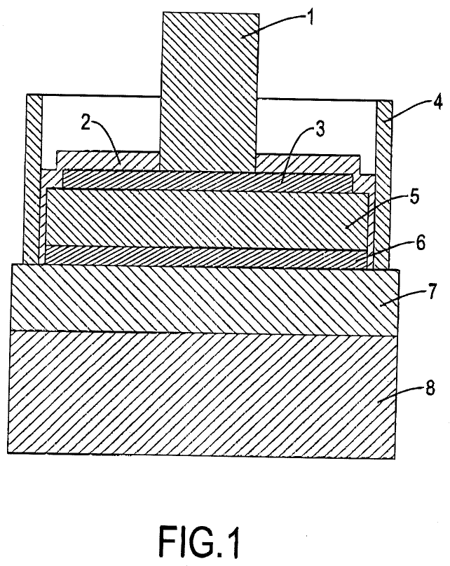

With reference to FIGS. 1, 2 and 3, a light-emitting diode in accordance with the present invention comprises a substrate (8), an n-type semiconductor layer (7, 7A, 7B), a light-emitting layer (6), a p-type semiconductor layer (5), a transparent electrode layer (3), an anode (1), a protective layer (2) and a cathode (4).

The substrate (8) has a top surface and a bottom surface.

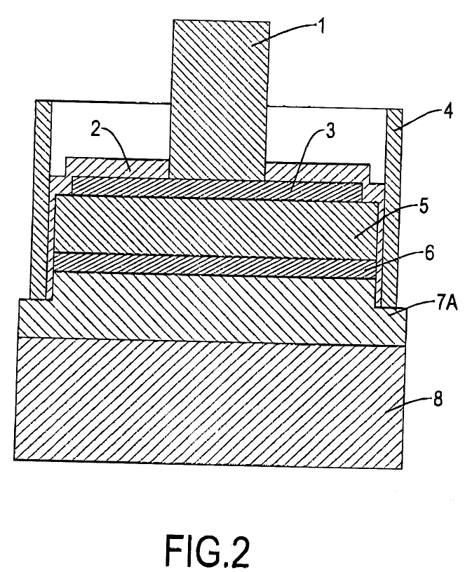

The n-type semiconductor layer (7, 7A, 7B) is formed on the top surface of the substrate (8) and has a side surface, a center section and an edge around the center portion. The edge of the n-type semiconductor layer (7A) may be thinner than the center section so as to form a step in the edge as shown in FIG. 2.

The light-emitting layer (6) is formed on the n-type semiconductor layer (7, 7A, 7B) at a side opposite to the substrate (8).

The p-type semiconductor layer (5) is formed on the light-emitting layer (6) at a side opposite to the n-type semiconductor (7). The n-type semiconductor layer (7, 7A, 7B), light-emitting layer (6) and p-type semiconductor layer (5) sequentially form a laminated structure and may be made of semiconductor materials such as GaIn material.

The transparent electrode layer (3) is formed on the p-type semiconductor layer (5) and may be made of a metallic oxide selected from the S group consisting of ITO, RuO₂, NiO₂, ZnO and a combination thereof. The transparent electrode layer (3) may have a height of one quarter of the wave length of the light emitted from the light-emitting diode. Notably, the transparent electrode layer (3) can improve an evenness of the current distribution of the light-emitting diode but is not necessary.

The anode (1) is formed on a top at a center of the transparent electrode layer (3), may be columnar and may be formed on the p-type semiconductor layer (5) if the light-emitting diode does not have the transparent electrode layer (3). The anode (1) may have a height higher than 2 um. An ohmic contact layer may be formed between the anode (1) and the p-type semiconductor layer (5).

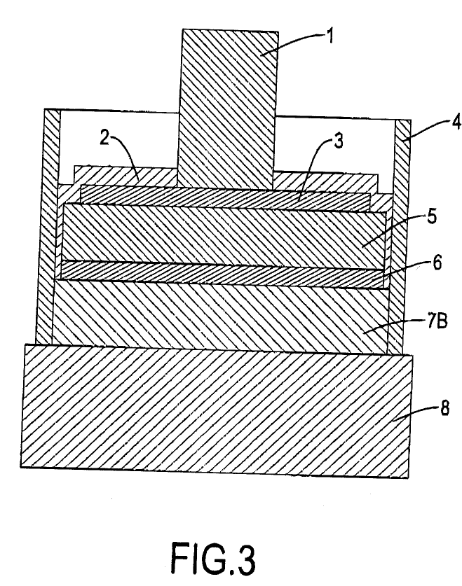

The cathode (4) is formed along the edge of the n-type semiconductor layer (7, 7A, 7B) and is in contact with the n-type semiconductor layer (7, 7A, 7B). The cathode (4) may be formed on the edge of the n-type semiconductor layer (7) as shown in FIG. 1. The cathode (4) may also be formed on the step of the n-type semiconductor layer (7A) as shown in FIG. 2 so as to increase the height of the cathode (4). The cathode (4) may also be formed on the substrate (8) in contact with the side surface of the n-type semiconductor layer (7B) to further increase the height of the cathode (4) as shown in FIG. 3.

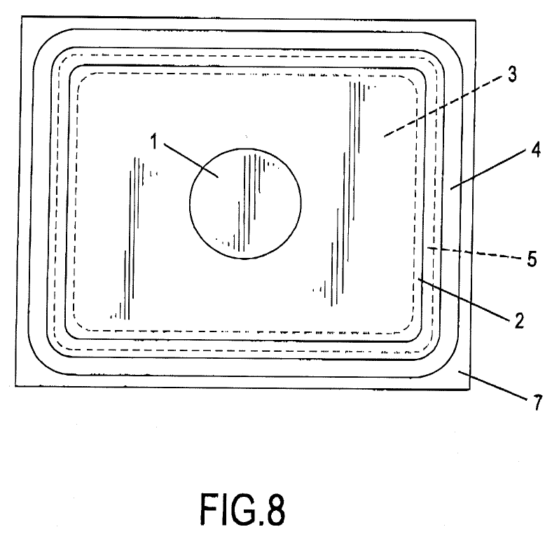

With further reference to FIG. 8, the cross section of the cathode (4) may be annular, such as a circular, oblong or polygonal loop-shaped composed of straight and curve lines and may have an identical shape from top to bottom. The cathode (4) may be made of a light non-absorption reflective metal or metallic oxide selected from the group consisting of the Cr, Al, Ag, Au, Ti, ITO, ZnO, RuO2 and a combination thereof so as to reduce the light absorption of the cathode (4). The cathode (4) may have a height higher than 2 urn. An ohmic contact layer may be formed between the cathode (4) and the n-type semiconductor (7) layer.

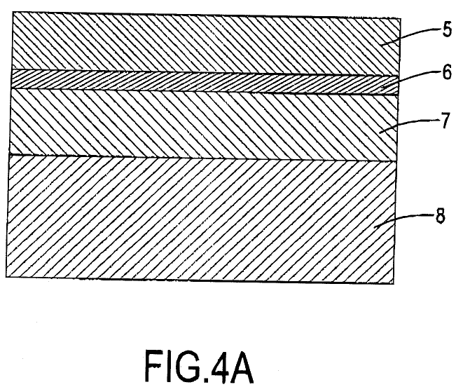

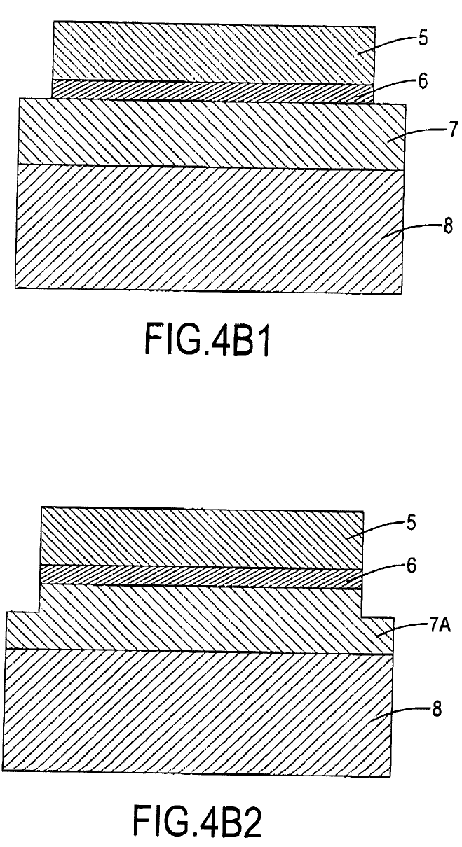

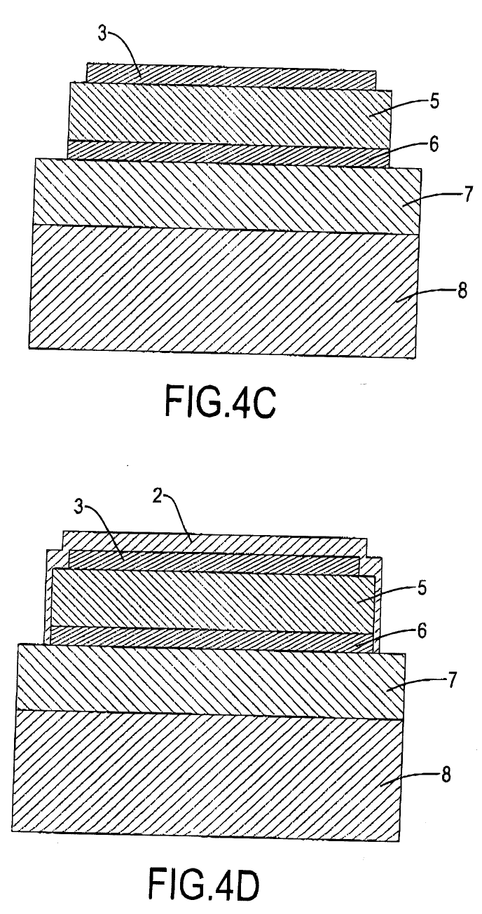

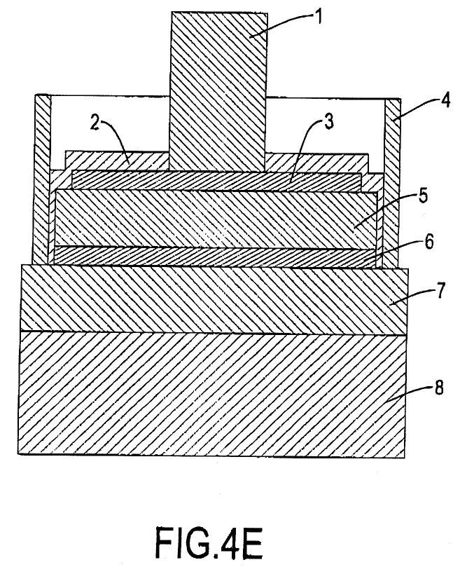

The protective layer (2) is formed on the top of the transparent electrode layer (3) and separates the cathode (4) from the transparent electrode layer (3) so as to prevent the cathode (4) from being in contact with the transparent electrode layer (3). The protective layer (2) may be formed on the p-type semiconductor layer (5) if the light-emitting diode does not have the transparent electrode layer (3). The anode (1) is mounted through the protective layer (2) to contact and connect with the transparent electrode layer (3) or the p-type semiconductor layer (5). Thus, the light-emitting diode does not malfunction due to electric leakage. The protective layer (2) may be made of an insulator such as SiO₂, Si₃N₄, SiNO, TiO₂, SOG or the like. With reference to FIGS. 4A to 4E, a manufacturing method for the light-emitting diode may comprise steps of providing a substrate (8), forming a laminated structure, etching, forming a transparent electrode layer (3), forming a protective layer (2) and forming a cathode (4) and an anode (1).

In the step of providing a substrate (8), the substrate (8) may be Si, sapphire, SiC, ZnO, GaN or the like and may have a height from 5 um to 100 um.

In the step of forming a laminated structure, the laminated structure is formed on the substrate (8) and comprises sequentially an n-type semiconductor layer (7), a light-emitting layer (6) and a p-type semiconductor layer (5) as shown in FIG. 4A. The laminated structure may be made of semiconductor materials like GaN and may be formed by using an epitaxial process.

In the step of etching, an edge of the laminated structure is etched and removed till an edge of the n-type semiconductor layer (7) is exposed as shown in FIG. 4B2. The edge of the n-type semiconductor layer (7A) can be further etched to make the edge of the n-type semiconductor layer (7A) be thinner than the center section of the n-type semiconductor layer (7A) so as to form a step on the edge as shown in FIG. 4B2.

In the step of forming a transparent electrode layer (3), the transparent electrode layer (3) is formed on the p-type semiconductor layer (5) by masking and coating as shown in FIG. 4C.

In the step of forming a protective layer (2), the protective layer (2) is formed to cover the transparent electrode layer (3) and the laminated structure but the edge of the n-type semiconductor layer (7) is still exposed as shown in FIG. 4D.

In the step of forming a cathode (4) and an anode (1), the cathode (4) is formed along the edge of the n-type semiconductor layer (7) and the anode (1) extends through the protective layer (2) and is formed on the top at a center section of the transparent electrode layer (3) as shown in FIG. 4E. The cathode (4) and the anode (1) may be formed by coating process sequentially or simultaneously and may have a height higher than 2 um. The anode (1) is connected to a lead (10). As mentioned above, the step of forming a transparent electrode layer (3) can also be neglected so the anode (1) is formed on the p-type semiconductor layer (5) directly.

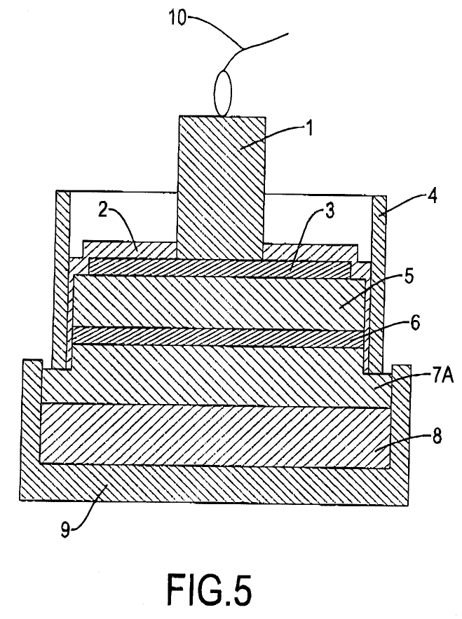

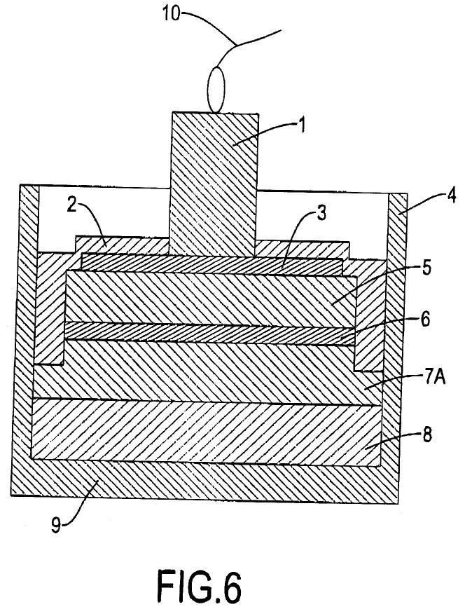

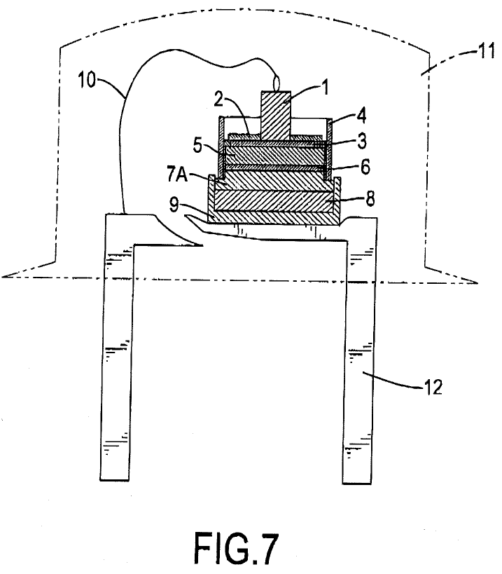

With reference to FIGS. 5 to 7, a package structure of the light-emitting diode is formed by cutting the substrate (8) of the above light-emitting diode to decrease the height of the substrate (8). Then a conductive material (9) such as plating metal or conductive adhesive are formed on the bottom surface of the substrate (8) and are in contact with the n-type semiconductor layer (7A). Finally, lead (10) is connected to the anode (1) to form a structure as shown in FIG. 5. Preferably, the conductive material (9) such as the plating metal or conductive adhesive (9) is formed integrally with the cathode (4) as a single part as shown in FIG. 6 so as to simplify manufacturing processes. Then, the lead (10) and the conductive material (9) such as the plating metal or conductive adhesive are respectively connected electrically to a lead frame (12) to form a package structure and the package structure is disposed in a cover (11) filled with epoxy resin as shown in FIG, 7. The lead frame (12) is used for being connected to an outer circuit. Because the cathode (4) is formed along the edge of the n-type semiconductor layer (7, 7A, 7B), electrical current can be distributed more evenly on a surface of the light-emitting diode. Additionally, when the cathode (4) is formed on the step of the n-type semiconductor layer (7A) or on the substrate (8) directly, the cathode (4) can be formed higher so as to increase electrical current and improve the evenness of the current distribution of the light-emitting diode. Furthermore, when the cathode (4) is made of light non-absorption reflective material, the light emitted from the light-emitting diode does not be absorbed by the cathode (4) and the brightness of the light-emitting diode is enhanced. The light-emitting efficiency of the light-emitted diode is 50% higher than that of the conventional light-emitted diode.

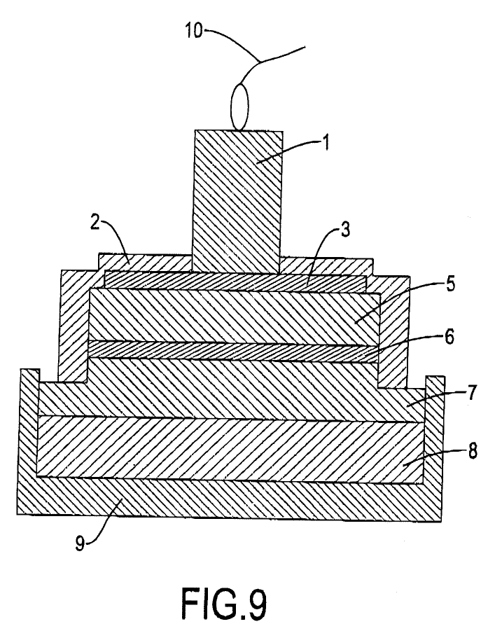

With reference to FIG. 9, in an alternative embodiment, a light-emitting diode in accordance with the present invention comprises a substrate (8), an n-type semiconductor layer (7), a light-emitting layer (6), a p-type semiconductor layer (5), a transparent electrode layer (3), an anode (1), a protective layer (2) and a conductive material (9). Consequently, to form a cathode is unnecessary.

To manufacture a light-emitting diode having a conductive material (9) but without a cathode, a step of forming a conductive material is acted after forming the anode, wherein the conductive material is formed on the bottom surface of the substrate and being in contact with the n-type semiconductor layer.

The invention can be applied on a high-brightness light-emitted diode.

Even though numerous characteristics and advantages of the present invention have been set forth in the foregoing description, together with details of the structure and function of the invention, the disclosure is illustrative only. Changes may be made in detail, especially in matters of shape, size and arrangement of parts within the principles of the invention to the full extent indicated by the broad general meaning of the terms in which the appended claims are expressed.

What is claimed is:

1. A light-emitting diode comprising
a sapphire substrate having a top surface and a bottom surface;
an n-type semiconductor layer being formed on the top surface of the sapphire substrate and having a side surface, a center section and an edge around the center portion;
a light-emitting layer being formed on the n-type semiconductor layer;
a p-type semiconductor layer being formed on the light-emitting layer;
an anode being formed on the p-type semiconductor layer; and
a conductive material being formed on the bottom surface of the sapphire substrate and being in contact with the n-type semiconductor layer.

2. The light-emitting diode as claimed in claim 1, wherein the light-emitting diode further has a transparent electrode layer formed between the p-type semiconductor layer and the anode and covering the p-type semiconductor layer; and
the anode is formed on a center of the transparent electrode layer.

3. The light-emitting diode as claimed in claim 1 further comprising a cathode being formed along the edge of the n-type semiconductor layer and being in contact with the conductive material.

4. The light-emitting diode as claimed in claim 3, wherein
the edge of the n-type semiconductor layer is thinner than the center section of the n-type semiconductor layer to form a step in the edge; and
the cathode is formed on the step of the n-type semiconductor layer.

5. The light-emitting diode as claimed in claim 3, wherein the cathode is formed on the substrate in contact with the side surface of the n-type semiconductor layer.

6. The light-emitting diode as claimed in claim 3, wherein the conductive material is formed integrally with the cathode as a single part.

7. The light-emitting diode as claimed in claim 1, wherein the conductive material is a plating metal or a conductive adhesive.

8. A package structure of a light-emitting diode comprising
a sapphire substrate having a top surface and a bottom surface;
an n-type semiconductor layer being formed on the top surface of the sapphire substrate and having a side surface, a center section and an edge around the center portion;
a light-emitting layer being formed on the n-type semiconductor layer;
a p-type semiconductor layer being formed on the light-emitting layer;
an anode being formed on the p-type semiconductor layer;
a lead being connected to the anode; and
a conductive material being formed on the bottom surface of the sapphire substrate and being in contact with the n-type semiconductor layer, wherein
the lead and the conductive material are respectively connected electrically to a lead frame used for being connected to an outer circuit.

9. The package structure of a light-emitting diode as claimed in claim 8,
wherein the light-emitting diode further has a transparent electrode layer formed between the p-type semiconductor layer and the anode and covering the p-type semiconductor layer; and
the anode is formed on a center of the transparent electrode layer.

10. The package structure of a light-emitting diode as claimed in claim 8, wherein the package structure further comprises a cathode being formed along the edge of the n-type semiconductor layer and being in contact with the conductive material.

11. The package structure of a light-emitting diode as claimed in claim 10, wherein
the edge of the n-type semiconductor layer is thinner than the center section of the n-type semiconductor layer to form a step in the edge; and
the cathode is formed on the step of the n-type semiconductor layer.

12. The package structure of a light-emitting diode as claimed in claim 10, wherein the cathode is formed on the substrate in contact with the side surface of the n-type semiconductor layer.

13. The package structure of a light-emitting diode as claimed in claim 10, wherein the conductive material is formed integrally with the cathode as a single part.

14. The package structure of a light-emitting diode as claimed in claim 8, wherein the conductive material is a plating metal or a conductive adhesive.

15. A manufacturing method for a light-emitting diode comprising steps of
providing a sapphire substrate;
forming a laminated structure, wherein the laminated structure is formed on the sapphire substrate and comprises sequentially an n-type semiconductor layer, a light-emitting layer and a p-type semiconductor layer;
etching, wherein an edge of the laminated structure is etched and removed till an edge of the n-type semiconductor layer is exposed; and
forming an anode, wherein the anode is formed on the p-type semiconductor layer and is connected to a lead; and
forming a conductive material, wherein the conductive material is formed on the bottom surface of the sapphire substrate and being in contact with the n-type semiconductor layer, wherein the lead and the conductive material are respectively connected electrically to a lead frame used for being connected to an outer circuit.

16. The manufacturing method for a light-emitting diode as claimed in claim 15 further comprises a step of forming a transparent electrode layer after the step of etching,
wherein the transparent electrode layer is formed between the p-type semiconductor layer and the cathode and covers the p-type semiconductor layer; and
in the step of the forming the anode, the anode is formed on a center of the transparent electrode layer.

17. The manufacturing method for a light-emitting diode as claimed in claim 15, wherein the edge of the n-type semiconductor layer is etched to be thinner than the center section of the n-type semiconductor layer in the step of etching.

18. The manufacturing method for a light-emitting diode as claimed in claim 15 further comprises a step of forming a cathode after the step of etching,
wherein the cathode is formed on the edge of the n-type semiconductor and is in contact with conductive material.

19. The manufacturing method for a light-emitting diode as claimed in claim 18, wherein in the step of the forming the cathode, the cathode is formed integrally with the conductive material as a single part.

20. The manufacturing method for a light-emitting diode as claimed in claim 15, wherein in the step of forming the conductive material, the conductive material is a plating metal or a conductive adhesive.
